(19) United States
(12) Patent Application Publication
(10) Pub. No.: US 2024/0329145 A1
(43) Pub. Date: Oct. 3, 2024

(54) Electrochemical Spectroscopy with Amplitude Compensation

(71) Applicant: TEXAS INSTRUMENTS INCORPORATED, Dallas, TX (US)

(72) Inventors: Bassem IBRAHIM, Allen, TX (US); David P MAGEE, Allen, TX (US)

(21) Appl. No.: 18/193,156

(22) Filed: Mar. 30, 2023

(51) Int. Cl. G01R 31/389; G01R 31/367; H01M 10/42

(52) U.S. Cl. CPC G01R 31/389; G01R 31/367; H01M 10/4285

(57) ABSTRACT

An apparatus includes a measurement circuit, a high-pass filter circuit, and a processing circuit. The measurement circuit is configured to receive an electrical signal of a device under test (DUT) and generate a measurement signal representing the electrical signal. The high-pass filter circuit is configured to perform a high-pass filtering operation on the electrical signal or the measurement signal to generate a filtered measurement signal. The processing circuit is configured to generate a measurement spectrum of the DUT based on the filtered measurement signal.

### BACKGROUND

Spectroscopy measures device under test (DUT) response spectra to characterize behavior of the DUT as a function of frequency. One type of spectroscopy is electrochemical impedance spectroscopy (EIS), in which the DUT is a battery cell or a group of battery cells, and the measured response is battery impedance.

### SUMMARY

In one example, an apparatus includes a measurement circuit, a high-pass filter circuit, and a processing circuit. The measurement circuit is configured to receive an electrical signal of a device under test (DUT) and generate a measurement signal representing the electrical signal. The high-pass filter circuit is configured to perform a high-pass filtering operation on the electrical signal or the measurement signal to generate a filtered measurement signal. The processing circuit is configured to generate a measurement spectrum of the DUT based on the filtered measurement signal.

In another example, a method includes receiving an electrical signal of a DUT. The method also includes generating a measurement signal representing the electrical signal. The method further includes performing a high-pass filtering operation on the electrical signal or the measurement signal to generate a filtered measurement signal. The method yet further includes generating a measurement spectrum of the DUT based on the filtered measurement signal.

In a further example, a non-transitory computer-readable medium stores instructions that, when executed by a processor, cause the processor to receive a measurement signal from a measurement circuit. The measurement signal represents an electrical signal of a DUT. The instructions also cause the processor to perform a high-pass filtering operation on the measurement signal to generate a filtered measurement signal. The instructions yet further cause the processor to generate a measurement spectrum of the DUT based on the filtered measurement signal.

### BRIEF DESCRIPTION OF THE DRAWINGS

FIG. 1 is a circuit diagram of a device under test, such as a battery, in an example.

FIG. 2 is a circuit block diagram of a battery monitoring system coupled to battery cells in an example.

FIG. 3 is a block diagram of a system to compensate for low frequency amplitude variation in a measured parameter of a device under test in an example.

FIG. 4 is a block diagram of an example high-pass filter that can be part of the amplitude compensation circuit of FIG. 3.

FIG. 5 is graph of an example bode plot of the high-pass filter of FIG. 4.

FIG. 6 is a block diagram of another system to compensate for low frequency amplitude variation in a measured parameter of a device under test in an example.

FIG. 7 is a graph showing an example of amplitude compensation by the system of FIG. 3 during battery discharge.

FIG. 8 is a graph showing example voltage spectra with amplitude compensation by the system of FIG. 3 during battery discharge.

FIG. 9 is a graph showing an example of amplitude compensation by the system of FIG. 3 during battery charging.

FIG. 10 is a graph showing example voltage spectra with amplitude compensation by the system of FIG. 3 during battery charging.

FIG. 11 is a graph showing example impedance estimation error using the system of FIG. 3.

FIG. 12 is a flow diagram of a method for electrochemical impedance spectroscopy using the system of FIG. 3 or FIG. 6.

FIG. 13 illustrates an example hardware computing system that can implement techniques of example embodiments.

### DETAILED DESCRIPTION

In some cases, circuit models approximate electrical device behavior. One such electrical device is a battery cell or group of battery cells, referred to herein as a battery for simplicity. In some cases, rechargeable batteries power various portable devices, such as laptop computers, mobile phones, and electric vehicles (EVs), as well as provide supplemental energy for power grids. The ability to predict battery behavior while the battery provides a current is useful to control and regulate power provided to such devices. A useful battery model accurately predicts voltage, current, and state-of-charge (SOC) while environmental conditions (e.g., temperature, pressure, humidity) vary, and the battery undergoes charging and discharging cycles.

Battery behavior while providing a current to a load depends on battery condition and environmental conditions. The battery condition can be characterized by its SOC, which refers to the level of available charge in the battery, and by its state-of-health (SOH), which refers to an amount (e.g., a percentage) of useful charge/discharge cycles remaining compared to the expected charge/discharge cycles that the battery is capable of. Environmental conditions including temperature (T), pressure and humidity also impact battery behavior.

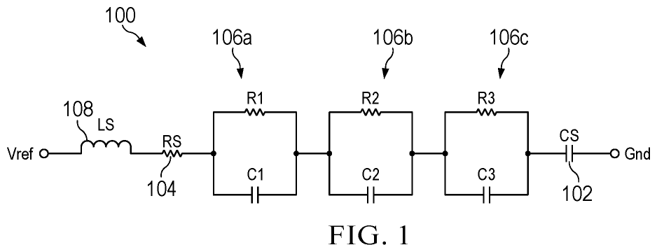

FIG. 1 is a circuit diagram of a model 100 of a DUT, which is a battery in this example. In the example of FIG. 1, the model 100 includes a series combination of a capacitor 102 (with capacitance CS), a resistor 104 (with resistance RS), and three resistor-capacitor (RC) stages 106. Each RC stage 106 includes a resistor and a capacitor in parallel. In some cases, the model 100 also includes a series inductor 108 (with inductance LS). In other cases, the model 100 may include more than three RC stages 106, fewer than three RC stages 106, or other numbers of RC stages 106. In the example of FIG. 1, the inductor 108 is coupled to a reference voltage terminal, the voltage at which is labelled Vref. The inductor 108 is also coupled to the resistor 104, which is also coupled to a first RC stage 106a. The first RC stage 106a (resistor R1 and capacitor C1) is coupled to a second RC stage 106b (resistor R2 and capacitor C2), which is also coupled to a third RC stage 106c (resistor R3 and capacitor C3). The third RC stage 106c is also coupled to the capacitor 102, which is also coupled to a ground node, the voltage at which is given by Gnd.

The series capacitor 102 represents a charge stored in the battery represented by the model 100. The series resistor 104 represents a resistance of the battery represented by the model 100. Each RC stage 106 represents a time constant for the variation of instantaneous voltage of the battery represented by the model 100. The series inductor 108 can represent parasitic inductance due to, for example, circuit board traces and wiring between circuit board and the battery represented by the model 100.

In examples of this description, EIS is useful to estimate an impedance of each battery cell at a given operating condition, which can depend on various factors such as the SOC, the temperature, and the age of the cell. In some cases, excitation signals are applied to the battery (or DUT) represented by the model 100 to determine its impedance. The excitation signals can be applied across a range of operating conditions, and are useful to estimate the circuit parameters of the model 100, which reflect the measured responses of the battery represented by the model 100.

In examples of this description, the battery cell SOC, SOH, and internal temperature are correlated to an impedance spectrum of the battery. The impedance spectrum for a battery is the ratio between the battery cell voltage and current in the frequency domain. As described, EIS is useful to measure battery impedance spectra to characterize the behavior of the battery. Accordingly, the cell SOC, SOH, and temperature can be determined from EIS measurements (e.g., from the measured impedance).

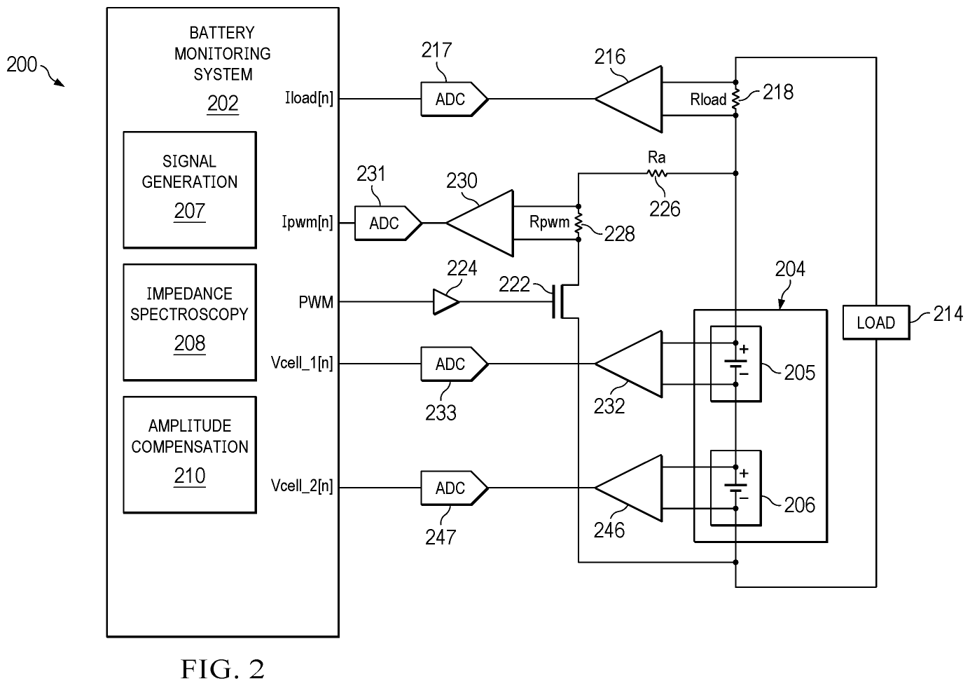

FIG. 2 is a circuit diagram of a system 200, including a battery monitoring system 202 coupled to a battery pack 204 containing two cells 205, 206 in an example. In other examples, the battery pack 204 can contain 16 cells, 24 cells, or another number of cells connected in series. Each cell 205, 206 that is connected in series can contain multiple cells in parallel, with each such set of cells connected in parallel forming a cell 205, 206. Accordingly, in the example of FIG. 2, the DUT includes the battery pack 204. In other examples, the DUT may include other devices than a battery pack 204.

The battery monitoring system 202 is configured to provide one or more excitation signals to the battery pack 204 (e.g., the DUT) and also to acquire one or more response signals from the battery pack 204, which correspond to parameter(s) being measured. As described below, the excitation signal(s) include a frequency component.

The battery monitoring system 202 includes signal generation circuit 207 (also referred to as an excitation circuit), which is configured to cause the excitation signals to be provided to the battery pack 204. The battery monitoring system 202 also includes an impedance spectroscopy circuit 208, which is configured to determine an impedance result, or spectra, of the battery pack 204, such as based on a ratio of a measured or provided battery pack 204 voltage signal and a measured or provided battery pack 204 current signal. The battery monitoring system 202 also includes amplitude compensation circuit 210, which is described below.

Each of the signal generation circuit 207, the impedance spectroscopy circuit 208, and the amplitude compensation circuit 210 can be implemented in hardware (e.g., one or more application-specific integrated circuits (ASICs)), as software executed by a hardware processor, or a combination of software and hardware. For example, the battery monitoring system 202 can include a hardware processor or processing circuit configured to execute instructions (e.g., stored in a non-transitory computer-readable medium, such as a memory). Responsive to the processor executing the instructions, the processor is configured to perform the functionality described herein, including amplitude compensation and generation of a measurement spectrum of a battery based on amplitude compensated battery measurements. The scope of the examples of this description is not limited to a particular physical implementation of any of the circuits of the battery monitoring system 202.

In the example of FIG. 2, the battery pack 204 is coupled to a load 214, which includes an inverter to control a motor in an EV in one example. A load current amplifier 216 is configured to receive a voltage across a load current sense resistor 218 (e.g., the load current amplifier 216 has a first input coupled to a first terminal of the load current sense resistor 218 and a second input coupled to a second terminal of the load current sense resistor 218), and to provide a voltage at its output that is proportional to the voltage across the load current sense resistor 218. Accordingly, the voltage provided at the output of the load current amplifier 216 is also proportional to the current provided to the load 214 by the battery pack 204, and the battery monitoring system 202 receives the voltage provided at the output of the load current amplifier 216 as signal Iload. In some examples, the output of the load current amplifier 216 is provided to an analog-to-digital converter (ADC) 217, which converts the analog output of the load current amplifier 216 to a digital value. In these examples, the battery monitoring system 202 receives the digital value output of the ADC 217 as Iload.

The battery monitoring system 202 is configured to generate a multi-cycle control signal, such as a pulse-width modulation (PWM) signal (labeled PWM), to control a transistor 222, which can be a field-effect transistor (FET). The battery monitoring system 202 provides the PWM signal to a gate driver 224, which drives a gate of the transistor 222 responsive to the PWM signal. A current measurement path is formed through resistor 226 (having a resistance Ra) and PWM current sense resistor 228 (having a resistance Rpwm) responsive to the transistor 222 conducting (e.g., being on/closed). No current flows through the current measurement path responsive to the transistor 222 not conducting (e.g., responsive to the transistor 222 being off/open).

A current measurement amplifier 230 has a first input coupled to a first terminal of the PWM current sense resistor 228 and a second input coupled to a second terminal of the PWM current sense resistor 228. The current measurement amplifier 230 is configured to receive a voltage across the PWM current sense resistor 228, and to provide a voltage at its output that is proportional to the voltage across the PWM current sense resistor 228. Accordingly, the voltage provided at the output of the current measurement amplifier 230 is also proportional to the current through the current measurement path, including resistors 226, 228, and the battery monitoring system 202 receives the voltage provided at the output of the current measurement amplifier 230 as signal lpwm. In some examples, the output of the current measurement amplifier 230 is provided to an ADC 231, which converts the analog output of the current measurement amplifier 230 to a digital value. In these examples, the battery monitoring system 202 receives the digital value output of the ADC 231 as lpwm.

A battery voltage amplifier 232 is configured to receive an alternating current (AC) voltage across the battery cell 205 (e.g., the battery voltage amplifier 232 has a first input coupled to a first terminal of the battery cell 205 and a second input coupled to a second terminal of the battery cell 205), and to provide a voltage at its output that is proportional to the voltage across the battery cell 205. The battery monitoring system 202 receives the voltage provided at the output of the battery voltage amplifier 232 as signal Vcell_1. In some examples, the output of the battery voltage amplifier 232 is provided to an ADC 233, which converts the analog output of the battery voltage amplifier 232 to a digital value. In these examples, the battery monitoring system 202 receives the digital value output of the ADC 233 as Vcell_1.

In an example in which the battery pack 204 includes an additional battery cell 206, a third battery voltage amplifier 246 is configured to receive a voltage across the battery cell 206 similarly as the battery voltage amplifier 232 receives the voltage across the battery cell 205, as described. The battery monitoring system 202 thus receives the voltage provided at the output of the third battery voltage amplifier 246 as signal Vcell_2. In some examples, the output of the third battery voltage amplifier 246 is provided to an ADC 247, which converts the analog output of the third battery voltage amplifier 246 to a digital value. In these examples, the battery monitoring system 202 receives the digital value output of the ADC 247 as Vcell_2.

As described, the battery monitoring system 202 is configured to provide one or more excitation signals to the battery pack 204 (e.g., the DUT). For example, the signal generation circuit 207 provides the multi-cycle PWM signal that controls the operation of the transistor 222, which sets the current through the current measurement path including resistors 226, 228. The current through the current measurement path is drawn from the battery pack 204 (e.g., the cells 205, 206 in the example of FIG. 2).

The signal generation circuit 207 is configured to control a duty cycle of the transistor 222 to set an amount of current through the current measurement path. A duty cycle of 100% corresponds to the transistor 222 being always closed within a cycle of the PWM signal, and a duty cycle of 0% corresponds to the transistor 222 being always open within a cycle of the PWM signal. The transistor 222 has a resistance equal to Rds(on) when it is closed. The average current through the current measurement path is approximately equal to the duty cycle multiplied by the battery pack 204 voltage, divided by the sum of Ra, Rpwm, Rds(on), and other resistances, such as trace resistance, along the current measurement path. The other resistances are ignored below for simplicity. Accordingly, the signal generation circuit 207, through the generation of the PWM signal, is configured to vary the average current drawn from the battery pack 204 between zero (e.g., responsive to a 0% duty cycle) and the battery pack 204 voltage divided by the sum of Ra, Rpwm and Rds(on) (e.g., responsive to a 100% duty cycle). The current through the resistors 226, 228 can add to the current provided by the battery pack 204 to the load 214.

As described, the battery monitoring system 202 receives an indication of the current through the resistors 226, 228 as the output of the current measurement amplifier 230 (lpwm). The battery monitoring system 202 is also configured to acquire one or more response signals from the battery pack 204, which correspond to parameter(s) being measured. For example, the Vcell_1 signal provided by the battery voltage amplifier 232 corresponds to the AC voltage across the battery pack 204. Accordingly, the battery monitoring system 202 is configured to provide an excitation signal to the battery pack 204, such as by varying the current through the resistors 226, 228 by controlling the duty cycle of the transistor 222 over time. The battery monitoring system 202 is also configured to measure a parameter (e.g., the voltage across the battery pack 204) that is responsive to the excitation signal.

The battery monitoring system 202 receives the indication of the current excitation signal (Ipwm) and the indication of the AC voltage parameter(s) of the battery pack 204 (Vcell_1, Vcell_2) in the time domain. The battery monitoring system 202 reconstructs the current and voltage across the battery cell 205, 206 responsive to Ipwm, and Vcell_1 or Vcell_2, respectively. For example, a voltage for battery cell 205 can be represented as V_{cell_1}[n], for each time sample n. Likewise, the current for battery cells 205, 206 can be written as:

$${I}_{cell} [ n ] = - ( {I}_{load} [ n ] + {I}_{pwm} [ n ] ) \qquad ( 1 )$$

for each time sample n. Similar values for the battery cell 206 (e.g., Vcell_2[n]) can be determined using the corresponding values (e.g., Vcell_2) for the battery cell 206. In this description, positive current indicates a current flowing into the battery pack 204, and thus negative current indicates a current flowing out of the battery pack 204.

In some examples, the battery monitoring system 202 can apply a transform operation, such as a discrete Fourier transform (DFT) operation, to samples of measurements of Vcell_1, Ipwm, and Vcell_2 (e.g., as EIS measurements) to transform the measurements from the time domain to the frequency domain. The transform operations allows other parameters, such as impedance, to be computed in the frequency domain to generate a spectroscopy of that parameter, such as an impedance spectroscopy. A DFT of each of the current and voltage time domain signals (e.g., Ipwm, and Vcell_1 (for battery cell 205) or Vcell_2 (for battery cell 206)) can be performed using a number of samples (e.g., n) of the time domain signals. The results of these DFTs are frequency domain representations of the current and voltage signals. The impedance for the battery cell 205 at each discrete frequency index k is computed responsive to the frequency domain representations of the current and voltage signals:

$${Z}_{cell \_ 1} [ k ] = \frac{{V}_{cell \_ 1} [ k ]}{{I}_{cell} [ k ]} \qquad ( 2 )$$

In an example, the battery monitoring system 202 can apply a window function to the samples acquired by the battery monitoring system 202, and perform the DFT on the samples with the window function applied. Provided that the sampling rate exceeds twice the signal bandwidth, the DFT can recover the underlying response spectra. Provided that the measured signals are periodic, the duration of the window function can be a multiple of the period of the measured signals.

In an example, the measured signals (e.g., the Ipwm signal from the current measurement amplifier 230, and the Vcell_1 signal or the Vcell_2 signal from the amplifiers 236, 248 respectively) are sinusoidal, and a sampled data interval covers an integer number of periods, the content of DFT (spectral energy) in a single frequency range (e.g., a single DFT frequency bin) can be sufficient to represent and characterize the spectra of the measured signals. However, in an example in which current is drawn from the battery pack 204 to conduct the measurements, the corresponding peak-to-peak cell voltage is not constant during the measurement. For example, in the equivalent circuit model 100 for the battery pack 204, the voltage across the series capacitor 102 decreases as the battery pack 204 discharges and increases as the battery pack 204 charges. Accordingly, the voltage signal(s) Vcell_1 and Vcell_2 are not periodic. A DFT of this non-periodic signal results in spectral energy being distributed across multiple frequency ranges, or frequency bins, which lead to non-zero spectral components in multiple frequency bins outside the frequency range of the measured signals. The presence of such non-zero spectral components in multiple frequency ranges, or frequency bins, can represent spectral leakage. Because of the spectral leakage, the spectral components in a particular DFT frequency bin may not provide an accurate representation of the spectra of the measured signals.

In an example, the battery monitoring system 202 is configured to control the transistor 222 to provide a sinusoidal current excitation signal to the battery pack 204. In one example, the current excitation signal is a single sinusoidal signal (e.g., the excitation signal is a single-tone signal and has a single frequency component). In another example, the current excitation signal is a linear combination of sinusoidal signals (e.g., the excitation signal is a multi-tone signal and has multiple frequency components). Irrespective of whether the excitation signal has a single or multiple frequency components, those frequency components correspond to frequency ranges of the result of the transform to the frequency domain. For example, the frequency components can be represented by spectral components in a DFT frequency bin.

As described above, the battery monitoring system 202 is configured to perform a transform operation, such as a DFT, on the measured current excitation signal (e.g., the Ipwm signal) and on the voltage response signal (e.g., the Vcell_1 signal) to transform the signals from time domain to frequency domain. In one example, the impedance spectroscopy circuit 208 includes circuitry configured to perform the DFT. In another example, the battery monitoring system 202 includes a hardware processor configured to execute instructions (e.g., stored in a non-transitory, computer-readable medium, such as a memory). Responsive to the processor executing the instructions, the processor can perform the DFTs. The ratio of the voltage DFT (or transform) to the current DFT (or transform) is the battery pack 204 impedance spectra (e.g., an EIS measurement), which is useful to characterize the battery pack 204. As described, the SOC, SOH, or temperature (T) parameters can be determined from the EIS measurement of the battery pack 204. The circuit parameters for the model 100 are then able to be determined or estimated responsive to the inferred parameters. Spectral leakage in the voltage and/or current DFT reduces the accuracy of the determination of the battery pack 204 impedance spectra, or EIS measurements, and subsequent processing of those EIS measurements.

In FIG. 1, the series capacitor 102 represents the charge storage of the battery pack 204, and is charged to the open circuit voltage (OCV) of the battery pack 204. As the battery pack 204 is discharged, the voltage on the series capacitor 102 in the model 100 decreases due to the current drawn from the battery pack 204. As described, the battery monitoring system 202 provides a sinusoidal current excitation signal to the battery pack 204, and the resulting voltage response signal is superimposed on the declining OCV (e.g., once a period of time has elapsed sufficient to allow transient response(s) associated with RC stage(s) 106 to settle). Because the OCV decreases over time as the battery pack 204 is discharged, the current excitation signal (which depends on the battery pack 204 voltage) and the voltage response signal include a low-frequency component, and thus are not periodic. Accordingly, without removing or attenuating the low-frequency component, the voltage and/or current DFTs may include spectral leakage.

In an example, the low-frequency variation of the battery pack 204 OCV during measurement by the battery monitoring system 202 can be represented by a linear function superimposed on the single-tone or multi-tone voltage response signal produced by providing the current excitation signal to the battery pack 204. For example, the effect of the low-frequency variation in the time domain can be represented by a linear voltage ramp. In the frequency domain, the amount of spectral leakage is proportional to the slope of the linear ramp. For example, for relatively small current excitation signals and a short measurement time, the resulting low-frequency signal varies slowly, which results in a relatively small negative slope for the voltage ramp. In one example, the amplitude of the current excitation signal is on the order of 100 milliamps (mA), and the frequency of the current excitation signal is approximately 1 millihertz (mHz), which results in a 1,000-second period. In this example, the measurement time is approximately three periods, or 3,000 seconds. A resulting slope of the voltage ramp can be approximately 10 microvolts (uV)/second. Accordingly, the frequency content of the voltage ramp falls primarily in a narrow frequency band, which is close to DC in the frequency domain (e.g., DFT bin zero). For longer measurement times (e.g., greater than three periods), the total change in the voltage ramp for the duration of the impedance measurement is also greater. Accordingly, for longer measurement times, the frequency content of the low-frequency signal falls in a broader band around DC in the frequency domain. The low-frequency signal produced by charging or discharging is thus a source of interference for lower-frequency excitation signals (e.g., having frequency content that falls in similar, lower-frequency DFT bins, such as near DC in the frequency domain).

Examples of this description address the foregoing by applying amplitude compensation to a measurement signal representing a measured parameter of a DUT (e.g., the measured parameter is responsive to providing an excitation signal to the DUT). In an example in which the DUT is the battery pack 204, the excitation signal can be the current excitation signal implemented by the battery monitoring system 202 controlling the transistor 222 (e.g., responsive to the lpwm signal). In this example, the measured parameter is a voltage response signal, such as Vcell_1 or Vcell_2, which are determined responsive to values provided by the battery voltage amplifier 232 and/or the battery voltage amplifier 246. The amplitude compensation can be provided by the amplitude compensation circuit 210.

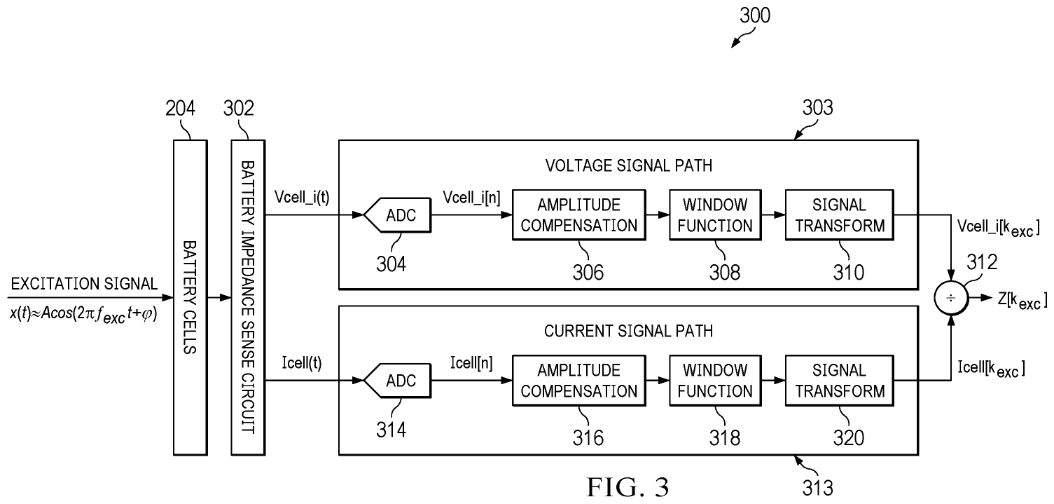

FIG. 3 is a block diagram of a system 300 to compensate for low frequency amplitude variation in a measured parameter of a device under test, such as battery pack 204. The system 300 includes circuit(s) that provide functionality similar to battery monitoring system 202 (e.g., signal generation circuit 207, and impedance spectroscopy circuit 208), as described. For example, an excitation signal (e.g., implemented by controlling the transistor 222) is provided by the signal generation circuit 207. In FIG. 3, x(t) represents a function of an excitation signal implemented by the PWM signal. A battery impedance sense circuit 302 can include a measurement circuit that provides measurements of battery pack 204 voltage and current in time domain. The battery impedance sense circuit 302 receives an electrical signal provided by the battery pack 204 and generates a measurement signal representing the electrical signal. The battery impedance sense circuit 302 generates the measurement signals Iload(t) and Ipwm(t), responsive to the providing of the excitation signal to the battery pack 204. The battery impedance sense circuit 302 also provides the measurement signal Vcell_i(t), responsive to the excitation signal being provided to the battery pack 204. As described, the current through the current measurement path is indicated to the battery monitoring system 202 as Ipwm, and the voltage across each battery cell in the battery pack 204 is indicated to the battery monitoring system 202 as Vcell_i(t). Accordingly, the battery impedance sense circuit 302 in FIG. 3 provides the time domain representations of various parameters measured by the battery monitoring system 202, described above with respect to FIG. 2.

The time domain representations of each cell voltage (Vcell_i(t)) and current (Icell(t)) are respectively provided to the voltage signal path 303 and the current signal path 313. The processing provided in the current signal path 313 is similar or identical to the processing provided in the voltage signal path 303. The voltage signal path 303 includes an ADC 304, an amplitude compensation circuit 306, a windowing circuit 308, and a signal transform circuit 310. The current signal path 313 includes an ADC 314, an amplitude compensation circuit 316, a windowing circuit 318, and a signal transform circuit 320. The ADC 314, the amplitude compensation circuit 316, the windowing circuit 318, and the signal transform circuit 320 may be similar to, or the same as, the ADC 304, the amplitude compensation circuit 306, the windowing circuit 308, and the signal transform circuit 310 respectively.

The ADC 304 digitizes (converts to digital samples) the signal Vcell_i(t) received from the battery impedance sense circuit 302, and provides the digital signal Vcell_i[n] to the amplitude compensation circuit 306. The amplitude compensation circuit 306 removes from the digital signal (or attenuates) the slowly-varying (low-frequency) signal components added to the signal Vcell_i(t) during battery charging or discharging. One example of the amplitude compensation circuit 306 includes a high-pass filter circuit (a digital high-pass filter (HPF)) that performs a high-pass filtering operation to correct for slow amplitude variation by removing the frequency components below the filter cut-off frequency. The frequency response (e.g., cut-off frequency) of the HPF can set be to a frequency lower than the lowest frequency of the excitation signal.

The windowing circuit 308 receives the amplitude compensated signal provided by the amplitude compensation circuit 306, and applies a window function to the received signal. For example, the windowing circuit 308 can multiply a selected number of consecutive samples of the received signal by a window function such as a cosine function that is maximum at the middle of a DFT interval and decreases to zero at the start and the end of the DFT interval to ensure continuity of the signal at the start and end of the DFT interval.

The signal transform circuit 310 applies a mathematical transform (e.g., a DFT) to transform the time domain output signal of the windowing circuit 308 to the frequency domain signal Vcell_i[k_{exc}].

The amplitude compensation provided by the amplitude compensation circuit 306 and window function applied by the windowing circuit 308 reduce spectral leakage in the output of the signal transform circuit 310 which results in provision of accurate frequency domain data by the signal transform circuit 310 for impedance estimation. This approach can be less dependent on the voltage amplitude variation pattern and can be more effective in removing the non-linear voltage amplitude variation that occurs during battery charging and discharging. Since the voltage variation is very slow compared to the typical frequency of the excitation signal that is useful for battery parameter estimation, the amplitude compensation circuit 306 with a cut-off frequency equal to the minimum excitation frequency can remove most of the voltage amplitude variation in the time domain to reduce the spectral leakage significantly in the excitation frequency bins after DFT and provide accurate impedance estimation.

The operations of the current signal path 313 with respect to the current signal Icell(t) received from the battery impedance sense circuit 302 can be the same as the operations described above for the voltage signal path 303. The current signal path 313 provides frequency domain output signal Icell[k_{exc}] representing the amplitude compensated and windowed spectra of the measured current Icell(t).

The divider 312 receives Vcell_i[k_{exc}] from the voltage signal path 303 and Icell[k_{exc}] from the current signal path 313, and divides Vcell_i[k_{exc}] by Icell[k_{exc}] to determine the impedance spectra of the battery pack 204 for each value of k_{exc}.

The amplitude compensation circuit 306 and the amplitude compensation circuit 316 can include any of various digital HPF architectures. Some examples of the amplitude compensation circuit 306 and the amplitude compensation circuit 316 can implement a 2^{nd} order infinite impulse response (IIR) digital HPF with a transfer function:

$$H ( z ) = \frac{Y ( z )}{X ( z )} = \frac{{b}_{0} + {b}_{1} {z}^{- 1} + {b}_{2} {z}^{- 2}}{1 - {a}_{1} {z}^{- 1} - {a}_{2} {z}^{- 2}} \qquad ( 3 )$$

The IIR digital filter can be implemented using a small number of additions and multiplications. The HPF with transfer function of equation (3) is defined by a difference equation:

$$y [ n ] = {b}_{0} x [ n ] + {b}_{1} x [ n - 1 ] + {b}_{2} x [ n - 2 ] + {a}_{1} y [ n - 1 ] + {a}_{2} y [ n - 2 ] \qquad ( 4 )$$

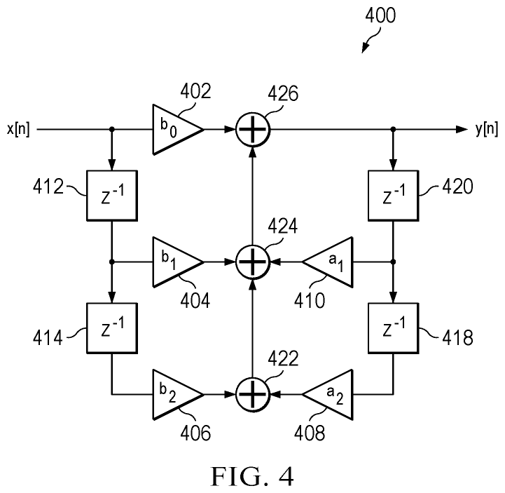

FIG. 4 is a block diagram of an implementation of an HPF 400 according to equation (4) that can be part of the amplitude compensation circuit 306 and the amplitude compensation circuit 316. In FIG. 4 the gain elements 402, 404, 406, 408, and 410 implement the coefficients b₀, b₁, b₂, a₁, and a₂ of equation (4). The delay elements 412, 414, 418, and 420 implement the negative time indexing of equation (4). The summation elements 422, 424, and 426 implement the additions of equation (4).

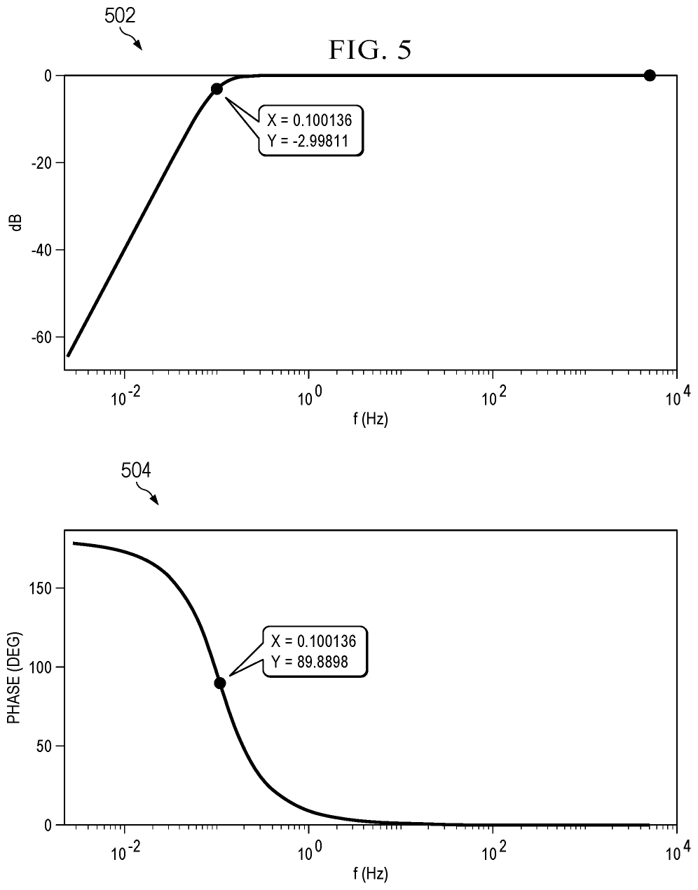

FIG. 5 is graph of an example bode plot of the HPF 400. FIG. 5 includes a graph 502 of gain and a graph 504 of phase of the HPF 400. The graph 502 shows that the HPF 400 has an attenuation of 40 dB/decade at frequencies below the cut-off frequency f_{c} (f_{c}=0.1 Hz in FIG. 5). The HPF 400 can efficiently remove the DC and the voltage variation from the battery voltage measurement by setting f_{c} to the minimum excitation frequency to make sure that all of the excitation signal is passed to the signal transform circuit 310 and at the same time eliminate the DC and slow varying amplitude.

In a digital HPF, the initial settling time of the HPF output is inversely proportional to the filter cut-off frequency f_{c}. For very small f_{c}, less than 0.1 Hz, the HPF settling time can be relatively long (e.g., multiple tens of seconds) which can delay operations dependent of the HPF output (e.g., battery monitoring functions). The amplitude compensation circuit 306 and the amplitude compensation circuit 316 can reduce this settling time by initializing the filter to a non-zero value that is equal to the average input value of the HPF. In the system 300, the HPF input is a battery signal (e.g., Vcell) with average DC voltage that varies slowly during battery charging or discharging. The amplitude compensation circuit 306 and the amplitude compensation circuit 316 can initialize the HPF by determining the average of the battery signal for a short period of time (less than 0.1 seconds) before starting the HPF and using the average to initialize the feedback path (e.g., an internal register in the feedback path (at the input of the delay element 420)) of the HPF. This filter initialization approach can significantly reduce the initial settling time of the HPF to enhance the performance of the battery monitoring functions based on the output of the amplitude compensation circuit 306 and the amplitude compensation circuit 316.

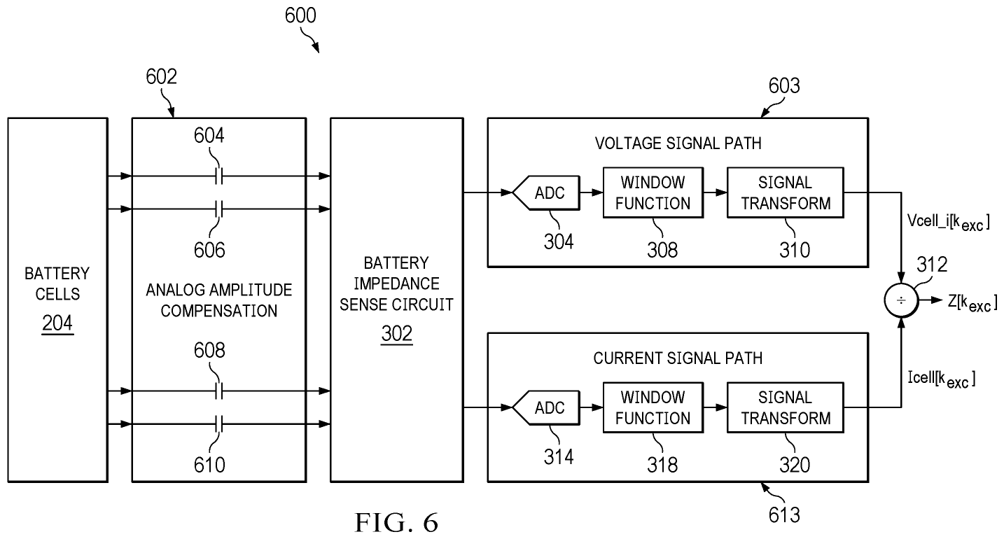

FIG. 6 is a block diagram of a system 600 to compensate for low frequency amplitude variation in a measured parameter of a device under test in an example. The system 600 implements amplitude compensation in analog circuitry rather than in digital circuitry (as in the HPF 400). The system 600 includes the battery pack 204, an analog amplitude compensation circuit 602, the battery impedance sense circuit 302, a voltage signal path 603, and a current signal path 613. The divider 312 is coupled to the voltage signal path 603 and a current signal path 613, and operates as described with regard to FIG. 3. The voltage signal path 603 includes the ADC 304, the windowing circuit 308, and the signal transform circuit 310 as described with regard to FIG. 3. The current signal path includes the ADC 314, the windowing circuit 318, and the signal transform circuit 320 as described with regard to FIG. 3. The analog amplitude compensation circuit 602 is coupled between the battery pack 204 and the battery impedance sense circuit 302. The analog amplitude compensation circuit 602 includes capacitors 604, 606, 608, and 610 each coupled between the battery pack 204 and the battery impedance sense circuit 302 to block DC signals from passing from the battery pack 204 to the battery impedance sense circuit 302. The capacitors 604 and 606 act as a high-pass filter that removes the low-frequency components of the AC voltage signal provided to the voltage signal path 603 according to the cut-off frequency of the filter as set by the capacitance values of the capacitors 604 and 606. The capacitor 604 can be coupled between a first terminal of a battery and a first input of an amplifier, and the capacitor 606 can be coupled between a second terminal of the battery and a second terminal of the amplifier. Similarly, the capacitors 608 and 610 act as a high-pass filter that removes the low-frequency components of the AC current signal provided to the current signal path 613 according to the cut-off frequency of the filter as set by the capacitance values of the capacitors 608 and 610. The capacitor 608 can be coupled between a first terminal of a sense resistor and a first input of an amplifier, and the capacitor 610 can be coupled between a second terminal of a sense resistor and a second terminal of an amplifier.

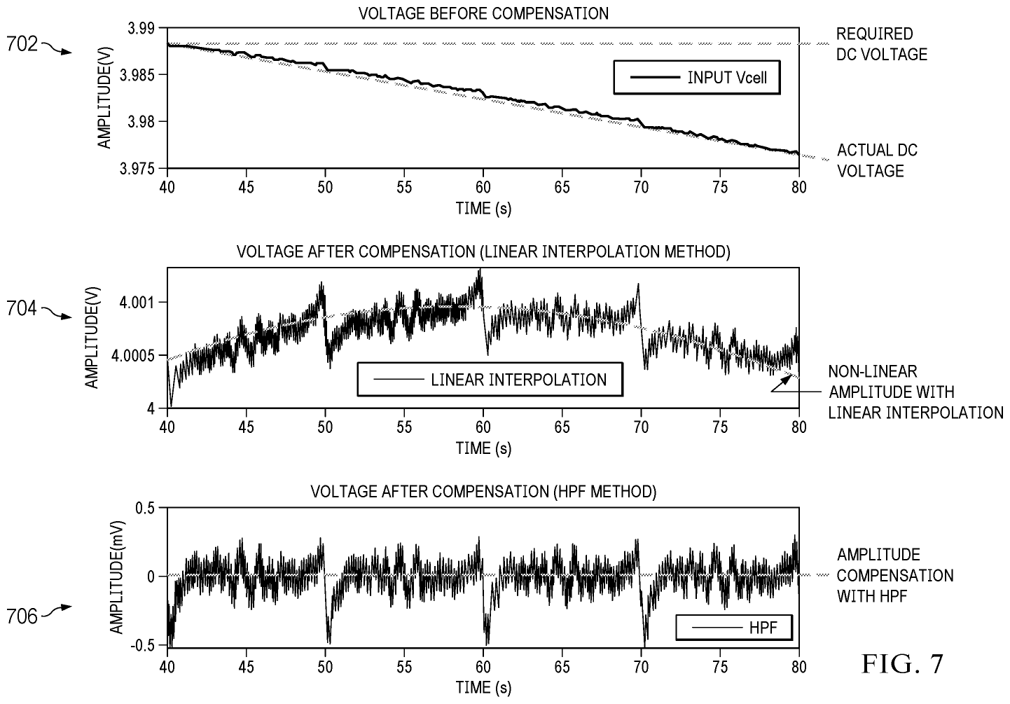

FIG. 7 is a graph showing an example of amplitude compensation by the system 300 or system 600 with battery discharging. FIG. 7 includes graph 702, graph 704, and graph 706. Graph 702 shows the battery voltage Vcell before amplitude compensation. The battery voltage has a slow non-linear variation (about-0.25 millivolts per second) in the DC as the battery is discharged. An excitation signal having frequencies ranging from 0.1 Hertz (Hz) to 1.5 Hz with an amplitude of about 1 millivolt peak-to-peak has been applied to the battery. The variation in the DC voltage due to discharging can cause substantial spectral leakage in the frequency domain.

Graph 704 shows an example result of compensating the amplitude of the battery voltage of graph 702 using a linear interpolation method. Amplitude compensation using the linear interpolation method leaves a significant non-linear amplitude residual that can cause spectral leakage.

Graph 706 shows an example result of compensating the amplitude of the battery voltage of graph 702 using the amplitude compensation circuit 306 or the analog amplitude compensation circuit 602. Graph 706 shows that the HPF provided in the amplitude compensation circuit 306 or the analog amplitude compensation circuit 602 eliminates the DC and slowly-varying voltage amplitude so that Vcell has constant DC centered around zero voltage after amplitude compensation. Accordingly, the amplitude compensation circuit 306 and the analog amplitude compensation circuit 602 remove or greatly reduce the low-frequency amplitude variation shown in graph 702 and reduce spectral leakage.

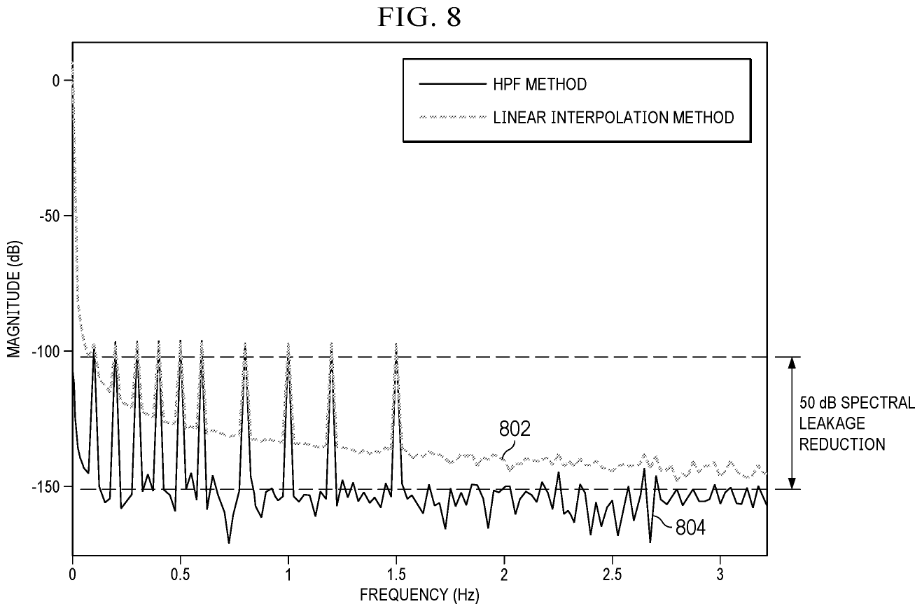

FIG. 8 is a graph showing a comparison of the frequency domain data derived from the time domain data of graphs 704 and 706 of FIG. 7. That is, FIG. 8 shows a comparison for frequency domain data derived using linear interpolation amplitude compensation versus using amplitude compensation with high-pass filtering as in the system 300 and the system 600. The graph 802 represents the spectra of the graph 704 and the graph 804 represents the spectra of the graph 706. FIG. 8 shows that the system 300 and the system 600 can provide a reduction in spectral leakage of about 50 dB relative to the linear interpolation method. Such a reduction in spectral leakage can substantially improve the impedance estimates produced using the frequency domain data.

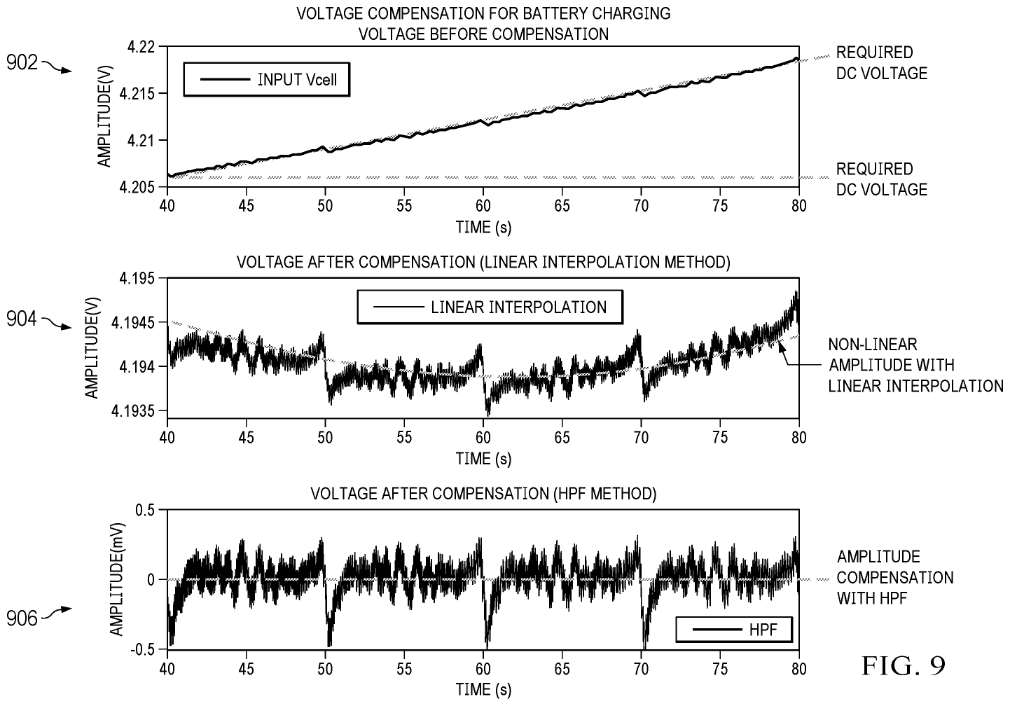

FIG. 9 is a graph showing an example of amplitude compensation by the system 300 or system 600 with battery charging. FIG. 9 includes graph 902, graph 904, and graph 906. Graph 902 shows the battery cell voltage Vcell before amplitude compensation. The battery voltage has a slow non-linear variation (increase) in the DC as the battery is charged. An excitation signal having frequencies ranging from 0.1 Hertz (Hz) to 1.5 Hz with an amplitude of about 1 millivolt peak-to-peak has been applied to the battery. The variation in the DC voltage can cause substantial spectral leakage in the frequency domain.

Graph 904 shows an example result of compensating the amplitude of the battery cell voltage of graph 902 using a linear interpolation method. Amplitude compensation using the linear interpolation method leaves a significant non-linear amplitude residual that can cause spectral leakage.

Graph 906 shows an example result of compensating the amplitude of the battery cell voltage of graph 902 using the amplitude compensation circuit 306 or the analog amplitude compensation circuit 602. Graph 906 shows that the HPF provided in the amplitude compensation circuit 306 or the analog amplitude compensation circuit 602 eliminates the DC and slowly-varying voltage amplitude so that Vcell has constant DC centered around zero voltage after amplitude compensation. Accordingly, the amplitude compensation circuit 306 and the analog amplitude compensation circuit 602 remove or greatly reduce the low-frequency amplitude variation shown in graph 902 and reduce spectral leakage.

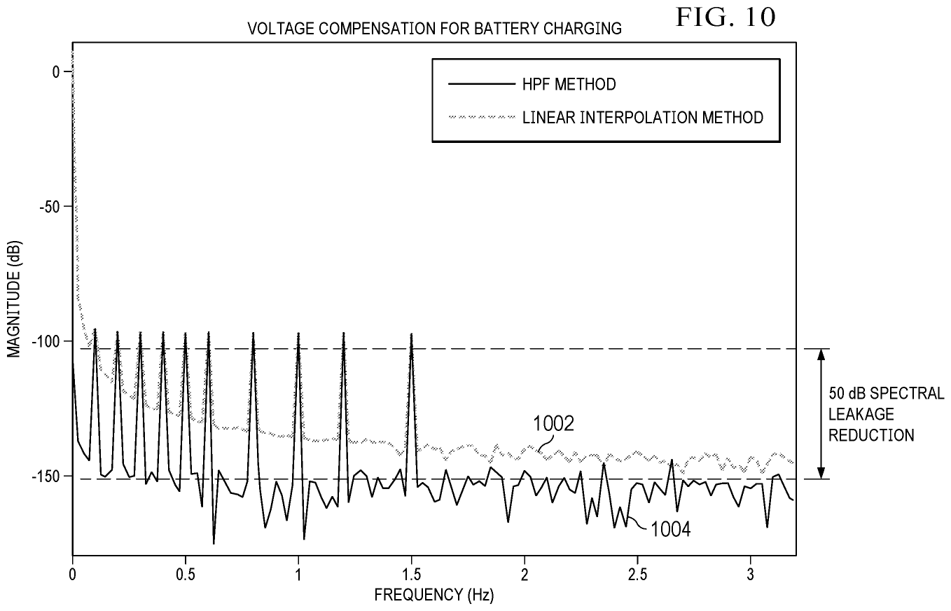

FIG. 10 is a graph showing a comparison of the frequency domain data derived from the time domain data of graphs 904 and 906 of FIG. 9. That is, FIG. 10 shows a comparison for frequency domain data derived using linear interpolation amplitude compensation versus using amplitude compensation with high-pass filtering as in the system 300 and the system 600. The graph 1002 represents the spectra of the graph 904 and the graph 1004 represents the spectra of the graph 906. FIG. 10 shows that the system 300 and the system 600 can provide a reduction in spectral leakage of about 50 dB relative to the linear interpolation method. Such a reduction in spectral leakage can substantially improve the impedance estimates produced using the frequency domain data.

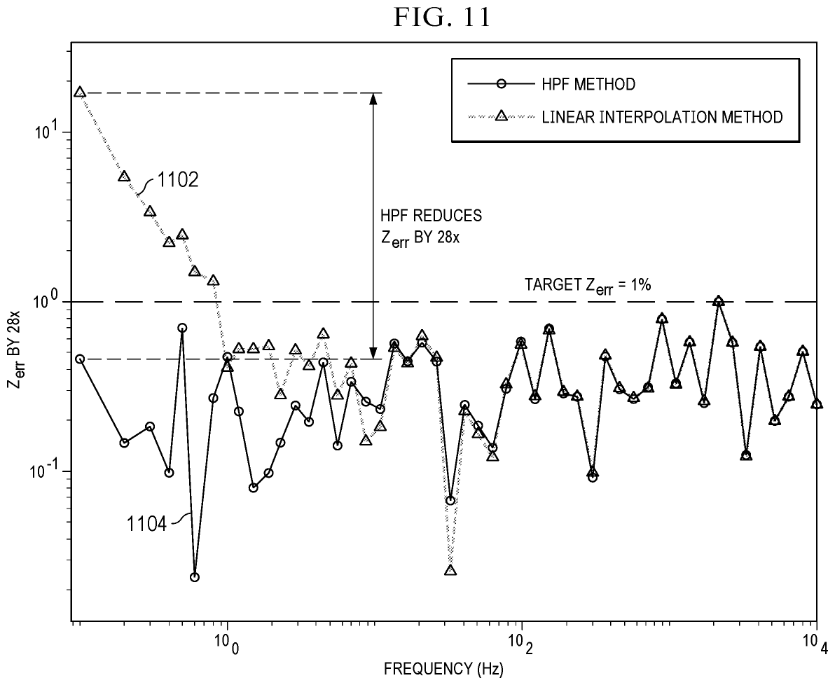

FIG. 11 is a graph showing a comparison of impedance error resulting from frequency data derived using linear interpolation amplitude compensation versus frequency data derived using amplitude compensation with high-pass filtering as in the system 300 and the system 600. The graph 1102 represents impedance error resulting from frequency data derived using linear interpolation amplitude compensation. The graph 1104 represents impedance error resulting from frequency data derived using amplitude compensation with high-pass filtering as in the system 300 and the system 600. Because of the reduction in spectral leakage provided by the system 300 and the system 600, the impedance error using the system 300 or the system 600 can be about 28 times lower at low frequencies than the error present when using amplitude compensation with linear interpolation. Using the system 300 or the system 600, reduces impedance estimation errors to less than one percent across the spectrum of interest (e.g., 0.1 Hz to 10 KHz).

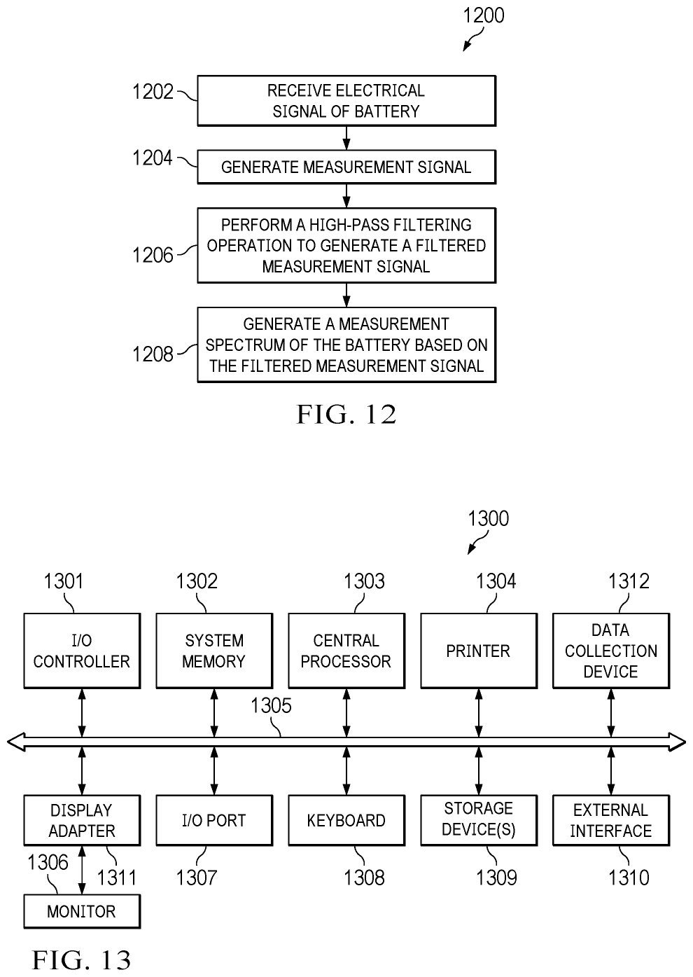

FIG. 12 is a flow diagram for an example method 1200 of EIS in accordance with various examples. The method 1200 can be performed by the system 200, which can include the system 300 or the system 600.

In step 1202, the battery pack 204 is being charged or discharged. The battery monitoring system 202 generates an excitation signal having a modulation frequency to modulate a parameter of the battery pack 204 (e.g., current or voltage of a battery of the battery pack 204) at the modulation frequency. The battery impedance sense circuit 302 receives an electrical signal of the battery. a measurement signal representing the parameter of a battery pack 204. The charging or discharging of the battery pack 204 causes a variation in an amplitude of the electrical signal. The electrical signal can be a voltage signal or a current signal.

In step 1204, a measurement signal representing the electrical signal is generated. The measurement signal can be, for example, the output of the amplifier 216, the amplifier 236, the amplifier 323, the amplifier 248, or the amplifier 246.

In step 1206, a high-pass filtering operation is performed on the electrical signal or the measurement signal to generate a filtered measurement signal. The high-pass filtering operation attenuates variation in the amplitude of the measurement signal or the electrical signal caused by charging or discharging the battery pack 204.

In step 1208, the battery monitoring system 202 generates an impedance spectrum of a battery of the battery pack 204 based on the filtered measurement signal. The impedance spectrum can be generated by dividing the voltage spectra of the battery derived from a voltage signal by the current spectra of the battery derived from a current signal.

The method 1200 can also include digitizing the measurement signal before the high-pass filtering operation of step 1204 where a digital HPF provides the filtering. For a digital HPF, the method can include initializing a feedback value applied in the HPF to an average value of the measurement. signal.

In an alternative example, the method 1200 can include filtering the measurement signal in the analog domain using an analog HPF before digitization. A corner frequency of the analog HPF can be lower than the lowest modulation frequency provided in the excitation signal.

FIG. 13 illustrates an example hardware computing system 1300 that can be part of battery monitoring system 202. The hardware computing system 1300 includes a number of example subsystems. The subsystems shown in FIG. 13 are interconnected via a system bus 1305. Additional subsystems such as a printer 1304, keyboard 1308, storage device(s) 1309, monitor 1306 (which is coupled to display adapter 1311) and others are shown. Peripherals and input/output (I/O) devices, which couple to I/O controller 1301, can be connected to the hardware computing system by any number of means such as input/output (I/O) port 1307 (e.g., USB, FireWire®). For example, I/O port 1307 or external interface 1310 (e.g. Ethernet, Wi-Fi, etc.) can be used to connect hardware computing system 1300 to a wide area network such as the Internet, a mouse input device, or a scanner. The interconnection via system bus 1305 allows the central processor 1303 to communicate with each subsystem and to control the execution of a plurality of instructions from system memory 1302 or the storage device(s) 1309 (e.g., a fixed disk, such as a hard drive, or optical disk), and the exchange of information between subsystems. The system memory 1302 and/or the storage device(s) 1309 may embody a computer-readable medium. In some examples, central processor 1303 can execute instructions stored in system memory 1302 and/or storage device(s) 1309 to perform the example computations and methods described above in, for example, FIG. 12. The central processor 1030 can use system memory 1302 to store the input data, output data, as well as intermediary data generated from the performance of the method. Another subsystem is a data collection device 1312, such as the battery impedance sense circuit 302, ADC 304, and ADC 314 of FIG. 3. Any of the data described herein can be output from one component to another component and can be provided to the user.

A hardware computing system can include the same components or subsystems, e.g., connected together by external interface 1310 or by an internal interface. In some embodiments, hardware computing systems, subsystem, or apparatus can communicate over a network. In such instances, one computer can be a client and another computer a server, where each can be part of a same computer system. A client and a server can each include multiple systems, subsystems, or components.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors are described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT—e.g., NPN transistor or PNP transistor), insulated gate bipolar transistors (IGBTs), and/or junction field effect transistor (JFET) may be used in place of or in conjunction with the devices disclosed herein. The transistors may be depletion mode devices, drain-extended devices, enhancement mode devices, natural transistors, or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input is the gate, and the current terminals are the drain and source. In the context of a BJT, the control input is the base, and the current terminals are the collector and emitter.

References herein to a FET being “on” means that the conduction channel of the FET is present and drain current may flow through the FET. References herein to a FET being “off” means that the conduction channel is not present and drain current does not flow through the FET. An “off” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” or “ground node” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero. Modifications are possible in the described embodiments, and other embodiments are possible, within the scope of the claims.

What is claimed is:

1. An apparatus, comprising:
a measurement circuit configured to receive an electrical signal of a device under test (DUT) and generate a measurement signal representing the electrical signal;
a high-pass filter circuit configured to perform a high-pass filtering operation on the electrical signal or the measurement signal to generate a filtered measurement signal; and
a processing circuit configured to generate a measurement spectrum of the DUT based on the filtered measurement signal.

2. The apparatus of claim 1, wherein the high-pass filter circuit is configured to attenuate a first component of the electrical signal or a second component of the measurement signal caused by charging or discharging of a battery.

3. The apparatus of claim 1, further comprising an excitation circuit configured to provide an excitation signal having an excitation frequency to the DUT;
wherein the electrical signal represents a response of the DUT to the excitation signal; and
wherein a frequency response of the high-pass filter circuit is based on the excitation frequency.

4. The apparatus of claim 2, further comprising an amplitude compensation circuit including the high-pass filter circuit and an analog-to-digital converter (ADC), the ADC configured to generate digital samples of the measurement signal; and
wherein the high-pass filter circuit is configured to perform the high-pass filtering operation on the measurement signal or the digital samples of the measurement signal.

5. The apparatus of claim 4, wherein the amplitude compensation circuit is configured to initialize a feedback value of the high-pass filter circuit to an average value of the measurement signal.

6. The apparatus of claim 1, wherein the high-pass filter circuit includes a capacitor coupled between the measurement circuit and the processing circuit.

7. The apparatus of claim 1, wherein the electrical signal includes at least one of a voltage signal or a current signal.

8. The apparatus of claim 1, wherein the electrical signal is a first electrical signal representing a voltage signal of the DUT, the measurement signal is a first measurement signal, the high-pass filtering operation is a first high-pass filtering operation, and the filtered measurement signal is a first filtered measurement signal;
wherein the measurement circuit is configured to receive a second electrical signal representing a current signal of the DUT and generate a second measurement signal representing the current signal;
wherein the high-pass filter circuit is configured to perform a second high-pass filtering operation on the second electrical signal or the second measurement signal to generate a second filtered measurement signal; and
wherein the processing circuit is configured to generate the measurement spectrum including an impedance spectrum based on the first and second filtered measurement signals.

9. The apparatus of claim 1, further comprising a windowing circuit configured to apply a window function to the filtered measurement signal.

10. A method, comprising:
receiving an electrical signal of a device under test (DUT);
generate a measurement signal representing the electrical signal;
performing a high-pass filtering operation on the electrical signal or the measurement signal to generate a filtered measurement signal; and
generating a measurement spectrum of the DUT based on the filtered measurement signal.

11. The method of claim 10, wherein performing the high-pass filtering operation attenuates a first component of the electrical signal or a second component of the measurement signal caused by charging or discharging of a battery.

12. The method of claim 10, further comprising:
providing an excitation signal having an excitation frequency to the DUT;
wherein the electrical signal represents a response of the DUT to the excitation signal; and
wherein a frequency response of the high-pass filtering operation is based on the excitation frequency.

13. The method of claim 11, further comprising:
generating digital samples of the measurement signal; and
performing the high-pass filtering operation on the measurement signal or the digital samples of the measurement signal.

14. The method of claim 13, further comprising initializing a feedback value applied in the high-pass filtering operation to an average value of the measurement signal.

15. The method of claim 10 further comprising providing the high-pass filtering operation by passing the measurement signal through a capacitor coupled to an input of an analog-to-digital converter.

16. The method of claim 10, wherein the electrical signal includes at least one of a voltage signal or a current signal.

17. The method of claim 10, wherein:
the electrical signal is a first electrical signal representing a voltage signal of the DUT;
the measurement signal is a first measurement signal;
the high-pass filtering operation is a first high-pass filtering operation;
the filtered measurement signal is a first filtered measurement signal; and
the method includes:
receiving a second electrical signal representing a current signal of the DUT; and
generating a second measurement signal representing the current signal;
performing a second high-pass filtering operation on the second electrical signal or the second measurement signal to generate a second filtered measurement signal; and
generating the measurement spectrum including an impedance spectrum based on the first and second filtered measurement signals.

18. A non-transitory computer-readable medium storing instructions that, when executed by a processor, cause the processor to:
receive a measurement signal from a measurement circuit, the measurement signal representing an electrical signal of a device under test (DUT);
perform a high-pass filtering operation on the measurement signal to generate a filtered measurement signal; and
generate a measurement spectrum of the DUT based on the filtered measurement signal.

19. The non-transitory computer-readable medium of claim 18, further storing instructions that, when executed by the processor, cause the processor to attenuate a first component of the electrical signal or a second component of the measurement signal caused by charging or discharging of a battery.

20. The non-transitory computer-readable medium of claim 18, further storing instructions that, when executed by the processor, cause the processor to provide an excitation signal having an excitation frequency to the DUT;
wherein the electrical signal represents a response of the DUT to the excitation signal; and
wherein a frequency response of the high-pass filtering operation is based on the excitation frequency.

21. The non-transitory computer-readable medium of claim 19, further storing instructions that, when executed by the processor, cause the processor to perform the high-pass filtering operation on digital samples of the measurement signal.

22. The non-transitory computer-readable medium of claim 21, further storing instructions that, when executed by the processor, cause the processor to initialize a feedback value applied in the high-pass filtering operation to an average value of the measurement signal.

23. The non-transitory computer-readable medium of claim 18, wherein:
the electrical signal is a first electrical signal representing a voltage signal of the DUT;
the measurement signal is a first measurement signal;
the high-pass filtering operation is a first high-pass filtering operation;
the filtered measurement signal is a first filtered measurement signal; and
the non-transitory computer-readable medium further stores instructions that, when executed by the processor, cause the processor to:
receive a second electrical signal representing a current signal of the DUT and generate a second measurement signal representing the current signal;
perform a second high-pass filtering operation on the second electrical signal or the second measurement signal to generate a second filtered measurement signal; and
generate the measurement spectrum including an impedance spectrum based on the first and second filtered measurement signals.
